(19) United States
(12) Patent Application Publication
(10) Pub. No.: US 2025/0278018 A1
(43) Pub. Date: Sep. 4, 2025

(54) THINNER COMPOSITION

(71) Applicant: DONGWOO FINE-CHEM CO., LTD., Iksan-si (KR)

(72) Inventors: Ji Min CHUN, Iksan-si (KR); Han Woo Park, Iksan -si (KR); Tae Kyung Lee, Iksan-si (KR); Somin Lee, Iksan-si (KR)

(73) Assignee: DONGWOO FINE-CHEM CO., LTD., Iksan-si (KR)

(21) Appl. No.: 19/051,701

(22) Filed: Feb. 12, 2025

(30) Foreign Application Priority Data
Feb. 29, 2024 (KR) 10-2024-0030082

(51) Int. Cl. G03F 7/004

(52) U.S. Cl. CPC G03F 7/0048

(57) ABSTRACT

A thinner composition containing an organic solvent with a Hansen solubility parameter by hydrogen bonding force (δh) value of 10 or more and a hydroxyalkylketone compound are disclosed. The thinner composition has improved EBR and RRC properties due to excellent solubility for photoresist films and spin-on hardmasks (SOHs). The thinner composition can reduce hump heights and improve coating film uniformity.

### CROSS REFERENCE TO RELATED APPLICATIONS

This application claims priority based on Korean Patent Application No. 10-2024-0030082, filed Feb. 29, 2024, the entire content of which is incorporated herein by reference in its entirety.

### TECHNICAL FIELD

The present invention relates to a thinner composition. More particularly, the present invention relates to a thinner composition with improved EBR and RRC properties due to excellent solubility for various photoresist films and spin-on hardmasks (SOHs), which can reduce hump heights and improve coating film uniformity.

### BACKGROUND ART

In the manufacturing process of semiconductor devices, the process of applying a resist on a wafer, transferring a designed pattern, and then etching it to create a fine circuit pattern such as a semiconductor integrated circuit is called the photolithography process. This is accomplished by applying, exposing, developing, etching, and peeling to realize the desired fine circuit pattern.

During the photolithography process, after the resist is uniformly applied on the surface of the wafer, it is necessary to remove the excess photoresist on the edge or backside of the wafer. This is because the presence of resist on the edge or backside of the wafer can cause various defects in subsequent processes such as etching, ion implantation, etc., resulting in a decrease in the yield of the entire semiconductor device.

In order to remove the resist present on the edge or backside of the wafer, a method of installing spray nozzles on the top and bottom of the edge portion of the wafer and spraying a thinner composition containing an organic solvent through the nozzles on the edge or backside of the wafer has been conventionally used.

For example, Korean Patent Publication No. 10-2013-0125029 discloses a thinner composition that can be used for such wafer processing, comprising: a) methoxypropanolacetic acid, b) methyl 2-hydroxyisobutyrate, and c) 1-methoxy-2-propanol.

Currently, photoresists such as i-line photoresists, KrF photoresists, ArF photoresists, EUV photoresists, and spin-on hardmasks (SOH) used in semiconductor lithography processes have different main components. Therefore, it is necessary to adjust the composition content of organic solvents to improve the solubility and applicability of all of them.

On the other hand, thinner compositions include high polarity components to improve solubility and edge bead removal (EBR) properties for high polarity photoresists. If the polarity is too high, it may accelerate the swelling of the photoresist from the EBR end toward the center of the wafer, resulting in a higher hump height. The high hump height reduces the usable area and increases the defects caused by the hump in the subsequent process, which reduces the yield.

Therefore, there is a need to develop a thinner composition having excellent solubility for various photoresist films and spin-on hardmasks (SOHs) to improve EBR and RRC properties and capable of reducing the hump height and improving the uniformity of the coating film.

### DISCLOSURE

### Technical Problem

An object of the present invention is to provide a thinner composition with improved EBR and RRC properties due to excellent solubility for various photoresist films and spin-on hardmasks (SOHs), which can reduce hump heights and improve coating film uniformity.

### Technical Solution

One embodiment of the present invention relates to a thinner composition comprising:
an organic solvent with a Hansen solubility parameter by hydrogen bonding force (δh) value of 10 or more; and
a compound of the following formula (1).

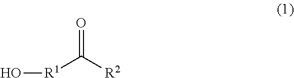

wherein,
R¹ is C₁-C₃ alkylene or C₇-C₁₅ arylalkylene, and
R² is C₁-C₆ alkyl.

In one embodiment of the present invention, the organic solvent with a Hansen solubility parameter by hydrogen bonding force (δh) value of 10 or more may be one or more selected from the group consisting of propylene glycol methyl ether, 2-hydroxyisobutyric acid methyl ester, diethylene glycol monobutyl ether, diethylene glycol monoethyl ether, ethyl lactate, butanol, and N,N-dimethylformamide.

In one embodiment of the present invention, R¹ may be C₁-C₃ alkylene.

In one embodiment of the present invention, the compound of the above formula (1) may be one or more selected from the group consisting of 3-hydroxy-3-methyl-2-butanone, 4-hydroxy-2-butanone, and 4-(4-hydroxyphenyl)-2-butanone.

In one embodiment of the present invention, the compound of the above formula (1) may be included in an amount of 0.01 to 2.5 wt % based on 100 wt % of the total thinner composition.

The thinner composition according to one embodiment of the present invention may further comprise an organic solvent with a Hansen solubility parameter by hydrogen bonding force (δh) value of less than 10.

In one embodiment of the present invention, the organic solvent with a Hansen solubility parameter by hydrogen bonding force (δh) value of less than 10 may be one or more selected from the group consisting of propylene glycol methyl ether acetate, cyclopentanone, n-butyl acetate, and 2-heptanone.

The thinner composition according to one embodiment of the present invention may comprise 1 to 35 wt % of the organic solvent with a Hansen solubility parameter by hydrogen bonding force (δh) value of 10 or more; 0.01 to 2.5 wt % of the compound of the above formula (1); and 64.5 to 98.5 wt % of the organic solvent with a Hansen solubility parameter by hydrogen bonding force (δh) value of less than 10.

The thinner composition according to one embodiment of the present invention may comprise 5 to 30 wt % of the organic solvent with a Hansen solubility parameter by hydrogen bonding force (δh) value of 10 or more; 0.1 to 1.5 wt % of the compound of the above formula (1); and 69 to 94 wt % of the organic solvent with a Hansen solubility parameter by hydrogen bonding force (δh) value of less than 10.

The thinner composition according to one embodiment of the present invention may be for one or more of a photoresist film and a spin-on hardmask (SOH).

In one embodiment of the present invention, the photoresist film may be a photoresist film for ArF, KrF, or EUV.

### Advantageous Effects

The thinner composition according to the present invention has excellent solubility for photoresist films and spin-on hardmasks (SOHs), resulting in improved EBR and RRC properties. The thinner composition according to the present invention can reduce the hump height and improve the uniformity of the coating film.

### BEST MODE

Hereinafter, the present invention will be described in more detail.

One embodiment of the present invention relates to a thinner composition comprising an organic solvent (A) with a Hansen solubility parameter by hydrogen bonding force (δh) value of 10 or more and a hydroxyalkylketone compound (B).

The thinner composition according to the present invention can be effectively used to reduce the amount of photoresist film and/or spin-on hardmask (SOH) used in semiconductor device and display manufacturing processes or eliminate them.

The thinner composition according to the present invention can reduce the hump height by controlling the polarity and reducing the rate at which the photoresist (PR) is swelled by the thinner from the EBR end toward the center of the wafer. Accordingly, the yield can be improved by increasing the usable area and reducing the defects caused by the hump in subsequent processes.

Further, the thinner composition according to the present invention can reduce the amount of photoresist and/or spin-on hardmask used in the process by increasing the reactivity of the composition forming the photoresist film and/or spin-on hardmask with the substrate surface, allowing a smaller amount to be dispersed more extensively on the substrate.

Furthermore, the thinner composition according to the present invention can improve the uniformity of the coating film.

Accordingly, the thinner composition according to the present invention is suitable for use in the process of forming photoresist films and/or spin-on hardmasks (SOHs) for purposes such as edge bead removal (EBR), back rinse, and resist reduced coating (RRC). For example, the photoresist film may be a photoresist film for ArF, KrF, or EUV.

Organic Solvent (a) with a δh Value of 10 or More

In one embodiment of the present invention, the organic solvent (A) with a Hansen solubility parameter by hydrogen bonding force (δh) value of 10 or more, preferably 10 to 15, is a component with high solubility for the acidic unit of the binder structure.

The organic solvent (A) with a Hansen solubility parameter by hydrogen bonding force (δh) value of 10 or more can increase the solubility for the organic coating film in all semiconductor processes, such as PR for ArF, PR for KrF, PR for EUV, or SOH, to reduce the occurrence of edge beads on the coating film and to reduce the hump height, thereby reducing particle defects in the fine patterning process. Furthermore, the organic solvent (A) with a Hansen solubility parameter by hydrogen bonding force (δh) value of 10 or more can improve the uniformity of the coating film.

In the present invention, the Hansen solubility parameter (ST) is a type of solubility parameter, which is an improved solubility parameter over the previously used Hildebrand solubility parameter. The Hansen solubility parameter (ST) is divided into three components, δd, δp, and δh, and expresses the solubility range of a substance in three-dimensional spatial coordinates. δd represents the solubility parameter by dispersion force, Op represents the solubility parameter by interdipole force, and δh represents the solubility parameter by hydrogen bonding force. For example, the Hansen solubility parameter (δT) (unit: (J/cm³)^{0.5}) is described and defined in ┌INDUSTRIAL SOLVENTS HANDBOOK┘ (pp. 35-68, Marcel Dekker, Inc., 1996), ┌DIRECTORY OF SOLVENTS┘ (pp. 22-29, Blackie Academic & Professional, 1996), and the like. In the present invention, the Hansen solubility parameters (δT and δd, δp, δh) are calculated using the HSPiP program.

Examples of the organic solvent with a Hansen solubility parameter by hydrogen bonding force (δh) value of 10 or more include propylene glycol methyl ether (δh: 12.1), 2-hydroxyisobutyric acid methyl ester (δh: 13.1), diethylene glycol monobutyl ether (δh: 10.6), diethylene glycol monoethyl ether (δh: 12.2), ethyl lactate (δh: 13.1), butanol (δh: 14.6), N,N-dimethylformamide (δh: 11.3), and the like, which can be used alone or in combination of two or more.

In one embodiment of the present invention, the organic solvent with a Hansen solubility parameter by hydrogen bonding force (δh) value of 10 or more may be included in an amount of 1 to 99.9 wt %, preferably 1 to 35 wt %, more preferably 5 to 30 wt %, based on 100 wt % of the total composition. When the organic solvent with a Hansen solubility parameter by hydrogen bonding force (δh) value of 10 or more is used in the above content range, EBR and RRC properties can be improved, the hump height can be reduced, and the uniformity of the coating film can be improved.

### Hydroxyalkylketone Compound (B)

In one embodiment of the present invention, the hydroxyalkylketone compound (B) serves to ensure solubility for various coating films.

Specifically, the hydroxyalkylketone compound is the compound of the following formula (1).

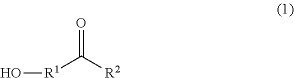

wherein,
R¹ is C₁-C₃ alkylene or C₇-C₁₅ arylalkylene, and
R² is C₁-C₆ alkyl.

As used herein, C₁-C₃ alkylene means a straight-chain or branched divalent hydrocarbon comprising one to three carbons, and includes, for example, but is not limited to, methylene, ethylene, propylene, and the like.

As used herein, C₇-C₁₅ arylalkylene means a complex group formed by linking C₆-C₁₂ arylene (an aromatic hydrocarbon group) with C₁-C₃ alkylene, and includes, for example, but is not limited to, phenylmethylene, phenylethylene, phenylpropylene, and the like.

As used herein, C₁-C₆ alkyl means a straight-chain or branched monovalent hydrocarbon comprising 1 to 6 carbons, and includes, for example, but is not limited to, methyl, ethyl, n-propyl, i-propyl, n-butyl, i-butyl, t-butyl, n-pentyl, n-hexyl, and the like.

In general, the solubility of the resist is different depending on the type of resist, and the composition of the thinner composition is designed differently in consideration of the target film. However, the thinner composition of the present invention includes the hydroxyalkylketone compound of the above structure, which has excellent solubility for all of ArF PR, KrF PR, EUV PR, and SOH (spin on hardmask) organic films, resulting in improved EBR and RRC properties for all of these organic films. Furthermore, the hydroxyalkylketone compound can reduce the hump height of the resist coating film that occurs during cleaning of the edge portion and improve the uniformity of the coating film.

In one embodiment of the present invention, in terms of improving EBR and RRC properties, reducing the hump height, and improving the uniformity of the coating film, R¹ is preferably C₁-C₃ alkylene.

Examples of the compound of the above formula (1) include 3-hydroxy-3-methyl-2-butanone, 4-hydroxy-2-butanone, and 4-(4-hydroxyphenyl)-2-butanone, and the like, which may be used alone or in combination of two or more.

In one embodiment of the present invention, the compound of the above formula (1) may be included in an amount of 0.01 to 2.5 wt %, preferably 0.1 to 1.5 wt %, based on 100 wt % of the total thinner composition. When the compound of the above formula (1) is used in the above content range, EBR and RRC properties can be improved, the hump height can be lowered, and the uniformity of the coating film can be improved. When the compound of the above formula (1) is included in an amount of 1.5 wt % or less, such as 0.1 to 1.5 wt %, EBR and RRC properties for SOH can be further improved, in particular, the edge of the coating film of SOH can exhibit an even shape. If the compound of the above formula (1) is included in an amount greater than 1.5 wt %, the edge of the coating film of SOH may exhibit an uneven shape.

Organic Solvent (C) with a δh Value of Less than 10

The thinner composition according to one embodiment of the present invention may further comprise an organic solvent (C) with a Hansen solubility parameter by hydrogen bonding force (δh) value of less than 10, preferably at least 5 and less than 10.

In one embodiment of the present invention, the organic solvent (C) with a Hansen solubility parameter by hydrogen bonding force (δh) value of less than 10 serves to balance the increased solubility caused by the organic solvent (A) with a Hansen solubility parameter by hydrogen bonding force (δh) value of 10 or more. The organic solvent (C) with a Hansen solubility parameter by hydrogen bonding force (δh) value of less than 10 prevents the coating film from dissolving too quickly and allows the EBR to be formed in an even shape.

Example of the organic solvent with a Hansen solubility parameter by hydrogen bonding force (δh) value of less than 10 include propylene glycol methyl ether acetate (δh: 9), cyclopentanone (δh: 5.2), n-butyl acetate (δh: 6.3), 2-heptanone (δh: 4.1), and the like, which may be used alone or in combination of two or more.

In one embodiment of the present invention, the organic solvent with a Hansen solubility parameter by hydrogen bonding force (δh) value of less than 10 may be included in an amount of 98.5 wt % or less, for example 64.5 to 98.5 wt %, preferably 69 to 94 wt %, based on 100 wt % of the total thinner composition. When the organic solvent with a Hansen solubility parameter by hydrogen bonding force (δh) value of less than 10 is used in the above content ranges, solubility for organic coating films can be adequately exhibited, resulting in lower hump heights with improved EBR and RRC properties, and improved uniformity of the coating film.

The thinner composition according to one embodiment of the present invention may further comprise additives such as surfactants, pH adjusters, and the like, if required.

As the surfactants, silicone-based surfactants, non-ionic surfactants, and the like may be used.

The thinner composition according to one embodiment of the present invention may comprise 1 to 35 wt % of the organic solvent with a Hansen solubility parameter by hydrogen bonding force (δh) value of 10 or more; 0.01 to 2.5 wt % of the compound of the above formula (1); and 64.5 to 98.5 wt % of the organic solvent with a Hansen solubility parameter by hydrogen bonding force (δh) value of less than 10.

The thinner composition according to one embodiment of the present invention may comprise 5 to 30 wt % of the organic solvent with a Hansen solubility parameter by hydrogen bonding force (δh) value of 10 or more; 0.1 to 1.5 wt % of the compound of the above formula (1); and 69 to 94 wt % of the organic solvent with a Hansen solubility parameter by hydrogen bonding force (δh) value of less than 10.

One embodiment of the present invention relates to a method of treating a substrate using the thinner composition described above.

A method of treating a substrate according to one embodiment of the present invention may comprise the steps of modifying the substrate with the thinner composition, and applying a photoresist or SOH on the modified substrate.

By performing the substrate modification step prior to applying the photoresist or SOH, the removal process can be performed effectively without causing tailing phenomenon in the edge bead removing (EBR) process, excellent coating uniformity can be maintained, and the reducing resist consumption (RRC) effect, which enables coating a wafer with a small amount of photoresist or SOH, can be maximized.

The modification step may be performed by applying the thinner composition according to the present invention in a conventional manner. For example, the modification step may be performed by spraying the thinner composition onto the center of a stationary substrate and then rotating the substrate so that the sprayed thinner composition is spread over the entire surface of the substrate. The amount of spraying may be from 0.1 cc to 5 cc.

The photoresist used in the application step may be at least one of photoresists for ArF, KrF and EUV. Further, the SOH used in the application step may be at least one of C—SOH and Si—SOH. When C—SOH is used, stability at high temperature is excellent, and when Si—SOH is used, optical properties are easily controllable.

The method of treating the substrate may further comprise, after the step of applying the photoresist or SOH, the step of treating the substrate with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

A method of treating a substrate according to one embodiment of the present invention may comprise the steps of applying a photoresist or SOH on a substrate to form a film, and treating the film with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

The method of treating the substrate may comprise the steps of treating the SOH-coated substrate with the thinner composition, then applying a photoresist, and then treating the substrate again with the thinner composition.

By applying the photoresist and subsequently treating the substrate again with the thinner composition in the above steps, excess photoresist and SOH applied on the edge or backside of the substrate can be quickly and effectively removed prior to the exposure process.

Hereinafter, the present invention will be described more specifically by means of examples, comparative examples, and experimental examples. These examples, comparative examples, and experimental examples are intended to illustrate the present invention only, and it is obvious to those skilled in the art that the scope of the present invention is not limited to them.

### Examples and Comparative Examples: Preparation of Thinner Compositions

Thinner compositions were prepared by mixing the components in the composition of Table 1 below (unit: wt %).

TABLE 1

| | (A)(wt %) | | | | (B)(wt %) | | | (C)(wt %) | | | |
|---|---|---|---|---|---|---|---|---|---|---|---|
| | A-1 | A-2 | A-3 | A-4 | B-1 | B-2 | B-3 | C-1 | C-2 | C-3 | C-4 |
| Example 1 | 15 | | | | 0.5 | | | 84.5 | | | |
| Example 2 | | 15 | | | 0.5 | | | 84.5 | | | |
| Example 3 | | | 15 | | 0.5 | | | 84.5 | | | |
| Example 4 | | | | 15 | 0.5 | | | 84.5 | | | |
| Example 5 | | 15 | | | 0.1 | | | 84.9 | | | |
| Example 6 | | 15 | | | 1 | | | 84 | | | |
| Example 7 | | 15 | | | 1.5 | | | 83.5 | | | |
| Example 8 | | 15 | | | 0.5 | | | | 84.5 | | |
| Example 9 | | 15 | | | 0.5 | | | | | 84.5 | |
| Example 10 | | 15 | | | 0.5 | | | | | | 84.5 |
| Example 11 | | 1 | | | 0.5 | | | 98.5 | | | |
| Example 12 | | 5 | | | 0.5 | | | 94.5 | | | |
| Example 13 | | 30 | | | 0.5 | | | 69.5 | | | |
| Example 14 | | 35 | | | 0.5 | | | 64.5 | | | |
| Example 15 | | 99.99 | | | 0.01 | | | | | | |
| Example 16 | | 99.9 | | | 0.1 | | | | | | |
| Example 17 | | 99.5 | | | 0.5 | | | | | | |
| Example 18 | | 99 | | | 1 | | | | | | |
| Example 19 | | 98 | | | 2 | | | | | | |
| Example 20 | | 97.5 | | | 2.5 | | | | | | |
| Example 21 | | 15 | | | | 0.5 | | 84.5 | | | |
| Example 22 | | 15 | | | | | 0.5 | 84.5 | | | |
| Comparative | | | | | 1 | | | 49 | 50 | | |
| Example 1 | | | | | | | | | | | |
| Comparative | | 15 | | | | | | 35 | 50 | | |
| Example 2 | | | | | | | | | | | |
| Comparative | | 15 | | | 5 | | | 80 | | | |
| Example 3 | | | | | | | | | | | |

A-1: Propylene glycol methyl ether (δh: 12.1)
A-2:2-hydroxyisobutyric acid methyl ester (δh: 13.1)
A-3: Ethyl lactate (δh: 13.1)
A-4: N,N-dimethylformamide (δh: 11.3)
B-1:3-hydroxy-3-methyl-2-butanone
B-2:4-hydroxy-2-butanone
B-3:4-(4-hydroxyphenyl)-2-butanone
C-1: Propylene glycol methyl ether acetate (δh: 9)
C-2: Cyclopentanone (δh: 5.2)
C-3: n-butyl acetate (δh: 6.3)
C-4:2-heptanone (δh: 4.1)

### Experimental Example 1

The thinner compositions prepared in the above examples and comparative examples were evaluated using a 12 inch Track (ACT-12, TEL) with the photoresist and SOH shown in Table 2 below under the conditions shown in Table 3 below.

The results are shown in Table 4 below.

TABLE 2

| Category | PR type |
|---|---|
| PR 1 | EUV PR A |
| PR 2 | ArF PR B |
| PR 3 | KrF PR C |
| PR 4 | Universal SOH |

TABLE 3

| | | | Rotational | |
|---|---|---|---|---|
| Performance | | Time | Speed | |
| Evaluation Step | | (seconds) | (rpm) | Description |
| 1 | Thinner | 3 | 0 | 4.0 cc of thinner |
| | Application | | | |
| 2 | Thinner Coating | 5 | 2000 | |
| 3 | PR Spray | 5 | 500 | 0.5 cc to 4 cc of PR |
| | Conditions | | | |
| 4 | PR Coating | 20 | 500~2000 | Adjust the film thickness |
| | | | | according to the |
| | | | | purpose of each type |
| | | | | of PR |
| 5 | EBR Conditions | 9 | 800 | Thinner spraying speed |
| | | | | 15 mL/min |
| 6 | Soft Baking | 50~60 | — | Temperature 90 to |
| | | | | 130° C. depending |
| | | | | on PR |

### (1) Edge Bead Removal (EBR) Performance Evaluation

A 12-inch silicon wafer substrate was coated with the photoresist or SOH listed in Table 2 above on the entire surface of the wafer under the evaluation conditions in Table 3 above, and an EBR test was conducted to remove excess photoresist at the edge using each thinner composition under the conditions listed in the 5th step of Table 3 above.

The EBR test was performed for three PRs and one SOH. The thinner compositions of the examples and comparative examples were supplied at a constant pressure from a pressurized canister equipped with a pressure gauge, and a total of 2.2 cc of the thinner was sprayed at a constant pressure during the EBR process. The evaluated substrates were examined under an optical microscope at 400× and 1,000× magnifications to check the straightness, uniformity, and tailing of the EBR line to evaluate the EBR according to the following evaluation criteria.

In addition, for the evaluation sample that shows the straightness and uniformity of the EBR line, the film thicknesses at 35 μm inward and 35 μm outward from the EBR line of the photoresist film were measured using a film thickness gauge (Dektak, Bruker) to derive the maximum film thickness value. Then, the average thickness of the photoresist film was excluded to calculate the hump height, which was evaluated according to the following evaluation criteria.

### <EBR Evaluation Criteria>

X: EBR line on the photoresist film is not uniform and tailing phenomenon occurs after EBR
Δ: No straightness and uniformity of EBR line on the photoresist film after EBR
◯: Straight but not uniform EBR line on the photoresist film after EBR
⊚: Straight and uniform EBR line on the photoresist film after EBR

### <Hump Height Evaluation Criteria>

x: Hump height is 1000 Å or more
Δ: Hump height is 500 Å to less than 1000 Å
◯: Hump height is 100 Å to less than 500 Å
⊚: Hump height is less than 100 Å

### (2) Uniformity Evaluation

Using the thinner compositions prepared in the examples and comparative examples, uniformity evaluation was performed by measuring film thicknesses at 61 points on the front surface of the wafer after coating the photoresist or SOH in Table 2 above, and calculating the standard deviation. Before applying the photoresist on the 12-inch silicon wafer, 4.0 cc of each thinner composition was applied for 3 seconds in a stationary state, followed by a 5-second substrate rotation at 2000 rpm to distribute the thinner over the entire surface of the wafer, as shown in Table 3. 1.0 cc of photoresist or SOH was coated, respectively. Uniformity was evaluated according to the following evaluation criteria.

### <Uniformity Evaluation Criteria>

x: Standard deviation σ value is 100 Å or more for PR film thicknesses at 61 points
Δ: Standard deviation σ value is 50 Å to less than 100 Å for PR film thicknesses at 61 points
◯: Standard deviation σ value is 20 Å to less than 50 Å for PR film thicknesses at 61 points
⊚: Standard deviation σ value is less than 20 Å for PR film thicknesses at 61 points

TABLE 4

| | EBR | | | | Hump height | | | | Uniformity | | | |
|---|---|---|---|---|---|---|---|---|---|---|---|---|
| | PR 1 | PR 2 | PR 3 | PR 4 | PR 1 | PR 2 | PR 3 | PR 4 | PR 1 | PR 2 | PR 3 | PR 4 |
| Example 1 | ⊚ | ⊚ | ⊚ | ◯ | ⊚ | ⊚ | ⊚ | ◯ | ⊚ | ⊚ | ⊚ | ◯ |
| Example 2 | ⊚ | ⊚ | ⊚ | ⊚ | ⊚ | ⊚ | ⊚ | ⊚ | ⊚ | ⊚ | ⊚ | ⊚ |
| Example 3 | ⊚ | ⊚ | ⊚ | ⊚ | ⊚ | ⊚ | ⊚ | ⊚ | ⊚ | ⊚ | ⊚ | ⊚ |
| Example 4 | ⊚ | ⊚ | ⊚ | ⊚ | ⊚ | ⊚ | ⊚ | ◯ | ⊚ | ⊚ | ⊚ | ⊚ |
| Example 5 | ⊚ | ⊚ | ⊚ | ⊚ | ⊚ | ⊚ | ⊚ | ⊚ | ⊚ | ⊚ | ⊚ | ⊚ |
| Example 6 | ⊚ | ⊚ | ⊚ | ⊚ | ⊚ | ⊚ | ⊚ | ⊚ | ⊚ | ⊚ | ⊚ | ⊚ |
| Example 7 | ⊚ | ⊚ | ⊚ | ⊚ | ⊚ | ⊚ | ⊚ | ⊚ | ⊚ | ⊚ | ⊚ | ⊚ |
| Example 8 | ⊚ | ⊚ | ⊚ | ⊚ | ⊚ | ⊚ | ⊚ | ⊚ | ⊚ | ⊚ | ⊚ | ⊚ |
| Example 9 | ⊚ | ⊚ | ⊚ | ⊚ | ⊚ | ⊚ | ⊚ | ⊚ | ⊚ | ⊚ | ⊚ | ⊚ |
| Example | ⊚ | ⊚ | ⊚ | ⊚ | ⊚ | ⊚ | ⊚ | ⊚ | ⊚ | ⊚ | ⊚ | ⊚ |
| 10 | | | | | | | | | | | | |
| Example | ◯ | Δ | Δ | Δ | ◯ | Δ | Δ | Δ | ◯ | Δ | Δ | Δ |
| 11 | | | | | | | | | | | | |
| Example | ⊚ | ⊚ | ⊚ | ⊚ | ⊚ | ⊚ | ⊚ | ⊚ | ⊚ | ⊚ | ⊚ | ⊚ |
| 12 | | | | | | | | | | | | |
| Example | ⊚ | ⊚ | ⊚ | ⊚ | ⊚ | ⊚ | ⊚ | ⊚ | ⊚ | ⊚ | ⊚ | ⊚ |
| 13 | | | | | | | | | | | | |
| Example | ◯ | Δ | Δ | Δ | ◯ | Δ | Δ | Δ | ◯ | Δ | Δ | Δ |
| 14 | | | | | | | | | | | | |
| Example | ⊚ | ◯ | ⊚ | Δ | ⊚ | ◯ | ⊚ | Δ | ⊚ | ◯ | ⊚ | ⊚ |
| 15 | | | | | | | | | | | | |
| Example | ⊚ | ◯ | ⊚ | ⊚ | ⊚ | ◯ | ⊚ | ⊚ | ⊚ | ◯ | ⊚ | ⊚ |
| 16 | | | | | | | | | | | | |
| Example | ⊚ | ◯ | ⊚ | ⊚ | ⊚ | ◯ | ⊚ | ⊚ | ⊚ | ◯ | ⊚ | ⊚ |
| 17 | | | | | | | | | | | | |
| Example | ⊚ | ◯ | ⊚ | ⊚ | ⊚ | ◯ | ⊚ | ⊚ | ⊚ | ◯ | ⊚ | ⊚ |
| 18 | | | | | | | | | | | | |
| Example | ⊚ | ◯ | ⊚ | ◯ | ⊚ | ◯ | ⊚ | ◯ | ⊚ | ◯ | ⊚ | ◯ |
| 19 | | | | | | | | | | | | |
| Example | ⊚ | ◯ | ⊚ | Δ | ⊚ | ◯ | ⊚ | Δ | ⊚ | ◯ | ◯ | ◯ |
| 20 | | | | | | | | | | | | |
| Example | ⊚ | ⊚ | ⊚ | ◯ | ⊚ | ⊚ | ◯ | ◯ | ⊚ | ⊚ | ◯ | ◯ |
| 21 | | | | | | | | | | | | |
| Example | ⊚ | ⊚ | ◯ | ◯ | ⊚ | ⊚ | ◯ | ◯ | ⊚ | ⊚ | ◯ | ◯ |
| 22 | | | | | | | | | | | | |
| Comparative | Δ | Δ | Δ | X | Δ | Δ | Δ | X | Δ | Δ | Δ | X |
| Example 1 | | | | | | | | | | | | |
| Comparative | Δ | Δ | Δ | X | Δ | Δ | Δ | X | Δ | Δ | Δ | X |
| Example 2 | | | | | | | | | | | | |
| Comparative | Δ | Δ | Δ | X | Δ | Δ | Δ | X | Δ | Δ | Δ | X |
| Example 3 | | | | | | | | | | | | |

As shown in Table 4 above, it was found that the thinner compositions of Examples 1 to 22 according to the present invention, which include an organic solvent with a Hansen solubility parameter by hydrogen bonding force (δh) value of 10 or more and a hydroxyalkylketone compound of a specific structure, have excellent EBR and RRC properties for photoresist films and spin-on hard masks (SOHs), and can reduce the hump height and improve the uniformity of the coating film.

On the other hand, the thinner compositions of Comparative Examples 1 and 2, which do not include either the organic solvents with a Hansen solubility parameter by hydrogen bonding force (δh) value of 10 or more or the hydroxyalkylketone compound of a specific structure, were found to have inferior EBR and RRC properties, low ability to reduce hump height, and poor uniformity of the coating film.

It was also found that the thinner composition of Comparative Example 3 with too high a content of hydroxyalkylketone compound exhibited poor EBR and RRC properties, low ability to reduce hump height, and poor uniformity of the coating film.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A thinner composition comprising:
an organic solvent with a Hansen solubility parameter by hydrogen bonding force (δh) value of 10 or more; and
a compound of formula (1): 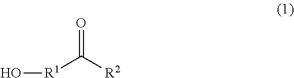
wherein,
R¹ is C₁-C₃ alkylene or C₇-C₁₅ arylalkylene, and
R² is C₁-C₆ alkyl.

2. The thinner composition according to claim 1, wherein the organic solvent with a Hansen solubility parameter by hydrogen bonding force (δh) value of 10 or more is one or more selected from the group consisting of propylene glycol methyl ether, 2-hydroxyisobutyric acid methyl ester, diethylene glycol monobutyl ether, diethylene glycol monoethyl ether, ethyl lactate, butanol, and N,N-dimethylformamide.

3. The thinner composition according to claim 1, wherein R¹ is C₁-C₃ alkylene.

4. The thinner composition according to claim 1, wherein the compound of formula (1) is one or more selected from the group consisting of 3-hydroxy-3-methyl-2-butanone, 4-hydroxy-2-butanone, and 4-(4-hydroxyphenyl)-2-butanone.

5. The thinner composition according to claim 1, wherein the compound of formula (1) is included in an amount of 0.01 to 2.5 wt % based on 100 wt % of the total thinner composition.

6. The thinner composition according to claim 1, further comprising an organic solvent with a Hansen solubility parameter by hydrogen bonding force (δh) value of less than 10.

7. The thinner composition according to claim 6, wherein the organic solvent with a Hansen solubility parameter by hydrogen bonding force (δh) value of less than 10 is one or more selected from the group consisting of propylene glycol methyl ether acetate, cyclopentanone, n-butyl acetate, and 2-heptanone.

8. The thinner composition according to claim 6, comprising:
1 to 35 wt % of the organic solvent with a Hansen solubility parameter by hydrogen bonding force (δh) value of 10 or more;
0.01 to 2.5 wt % of the compound of formula (1); and
64.5 to 98.5 wt % of the organic solvent with a Hansen solubility parameter by hydrogen bonding force (δh) value of less than 10.

9. The thinner composition according to claim 8, comprising:
5 to 30 wt % of the organic solvent with a Hansen solubility parameter by hydrogen bonding force (δh) value of 10 or more;
0.1 to 1.5 wt % of the compound of formula (1); and
69 to 94 wt % of the organic solvent with a Hansen solubility parameter by hydrogen bonding force (δh) value of less than 10.

10. The thinner composition according to claim 1, wherein the thinner composition is for one or more of a photoresist film and a spin-on hardmask (SOH).

11. The thinner composition according to claim 10, wherein the photoresist film is a photoresist film for ArF, KrF, or EUV.
